(19) United States
(12) Patent Application Publication
(10) Pub. No.: US 2008/0012640 A1
(43) Pub. Date: Jan. 17, 2008

(54) Unilateralized amplifier

(75) Inventor: Richard Campbell, Portland, OR (US)

Correspondence Address: CHERNOFF, VILHAUER, MCCLUNG & STENZEL, 1600 ODS TOWER, 601 SW SECOND AVENUE, PORTLAND, OR, 97204-3157, US

(73) Assignee: Cascade Microtech, Inc.

(21) Appl. No.: 11/582,917

(22) Filed: Oct. 17, 2006

Related U.S. Application Data
(60) Provisional application No. 60/830,877, filed on Jul. 14, 2006.

(51) Int. Cl. H03F 3/45; H03F 1/14

(52) U.S. Cl. 330/252; 330/292

(57) ABSTRACT

The effect of input signal frequency on the output of a differential amplifier is reduced by connecting the conductor of each of the input signal components to the respective conductor of the output signal component of opposite phase with a capacitor substantially equal to the parasitic capacitances interconnecting the terminals of the amplifier's transistors.

### CROSS-REFERENCE TO RELATED APPLICATIONS

This application claims the benefit of U.S. Provisional Application No. 60/830,877, filed Jul. 14, 2006.

### BACKGROUND OF THE INVENTION

The present invention relates to integrated circuits and, more particularly, to an integrated circuit based amplifier with improved frequency response.

Integrated circuits (ICs) comprise an arrangement of passive and active circuit elements, such as transistors, resistors and capacitors that are fabricated on a substrate or wafer. ICs are fabricated by a process of successively depositing layers of semi-conductive, conductive or insulating materials on the substrate and selectively etching portions of the deposited material. Deposition of a semi-conducting, conducting or insulating layer is followed by deposition of a layer of photosensitive material. The photosensitive material is exposed to light, through a precisely aligned mask, causing portions of the material to be chemically altered. Portions of the exposed photosensitive material are removed producing a photoresist layer with a pattern corresponding to the mask. A chemical etchant, applied to the surface, selectively removes the underlying layer of conductive, semi-conductive or insulating material except in those areas which are protected by the remaining photoresist. The remaining portions of the semi-conductor, conductor or insulator comprise a layer of one or more of the stratified, passive or active elements of the integrated circuit. The photoresist layer is removed from the exposed surface of the wafer and the process is repeated until all of the strata of the circuit's elements have been laid down.

ICs are economically attractive because large numbers of often complex circuits, such as microprocessors, can be inexpensively fabricated on the surface of a single wafer or substrate. Following fabrication the individual circuits are separated from each other and packaged as individual devices. However, as a consequence of the fabrication process and the resulting structure of the elements of the integrated circuit, the performance of ICs can vary substantially with the signal frequency. Electrical interconnections exist between many of the parts of the individual circuit elements and between parts of the circuit elements and the substrate on which the circuits elements are fabricated. These interconnections or parasitics are commonly capacitive and/or inductive in nature and produce impedances that are variable with frequency. For example, the terminals of transistors fabricated on semi-conductive substrates or wafers are typically capacitively interconnected, through the substrate, to the ground plane. Many integrated circuits utilize single ended or ground referenced signaling that is referenced a ground plane at the lower surface of the substrate on which the active and passive devices of the circuit are fabricated. As a result of the frequency dependent effects of these parasitic interconnections, the ground potential and the true nature of ground referenced signals becomes uncertain at higher frequencies.

Balanced or differential devices utilizing differential signals are more tolerant to poor radio frequency (RF) grounding than single ended devices making them attractive for high performance ICs. Referring to FIG. 1, a differential gain cell or amplifier 20 is a balanced device comprising two nominally identical circuit halves 20A, 20B. When the transistors 22 of the differential gain cell are biased with a DC potential provided, for examples by a current source 24 or a ground potential, and stimulated with a differential mode signal, comprising even (Sᵢ⁺¹) and odd (Sᵢ⁻¹) mode components of equal amplitude and opposite phase, a virtual ground is established at the symmetrical axis 26 of the two circuit halves. At the virtual ground, the potential at the operating frequency does not change with time regardless of the amplitude of the stimulating signal. The quality of the virtual ground of a balanced device is independent of the physical ground path and, therefore, balanced or differential circuits can tolerate poor RF grounding better than circuits operated with single ended signals. In addition, the two waveforms of the differential output signal (Sₒ⁺¹ and Sₒ⁻¹) are mutual references providing faster and more certain transitions from one binary value to the other for digital devices and enabling operation with a reduced voltage swing for the signal. Moreover, balanced or differential circuits have good immunity to noise, including noise at even-harmonic frequencies, because noise from external sources, such as adjacent conductors, tends to couple, electrically and electromagnetically, in the common mode and cancel in the differential mode and because signals that are of opposite phase at the fundamental frequency are in phase at the even harmonics.

While greater tolerance to poor RF grounding, increased resistance to noise and reduced power consumption make differential devices attractive for ICs that operate at higher frequencies, the linearity and stability of a differential amplifier is affected by the variable impedance resulting from the inherent parasitic interconnections of elements of the amplifier's integrated circuit. For example, the input and output of a differential gain cell, such as the differential gain cell 20, are typically capacitively interconnected as a result of parasitic capacitance connecting the terminals of the cell's transistors. Parasitic capacitance (C_{gd}) 40 between the gate 32 and the drain 32, a result of diffusion of the drain dopant under the oxide of the gate, is inherent and typical of MOS transistors. As a result of the transistor's gain, a change in the gate voltage produces an even larger change in the voltage at the transistor's drain. The application of differing voltages at the terminals of the parasitic gate-to-drain capacitor (C_{gd}) causes the capacitor to behave as a much larger capacitance magnifying its effect on the amplifier's output, a phenomenon known as the Miller effect. In addition, the performance of the differential amplifier is effected by parasitic capacitance (C_{ds}) 42 between the sources 32 and drains 34 and parasitic capacitance (C_{gg}) 44 between the gates and between the sources (Cₛₛ) 46 of the transistors resulting from the closely spaced arrangement of conductors and insulators making up the amplifier's integrated circuit. The impedance of the differential gain cell varies substantially with frequency, producing non-linearity and instability in the operation of the differential gain cell or amplifier and other devices that incorporate the differential gain cell.

What is desired, therefore, is an integrated circuit-based differential amplifier having improved frequency response.

### BRIEF DESCRIPTION OF THE DRAWINGS

FIG. 1 is a schematic illustration of a differential amplifier.

FIG. 2 is a schematic illustration of a Gilbert cell.

FIG. 3 is a schematic illustration of a unilateralized differential amplifier comprising metal oxide semiconductors.

FIG. 4 is a schematic illustration of a unilateralized differential amplifier comprising bipolar junction transistors.

### DETAILED DESCRIPTION OF PREFERRED EMBODIMENTS

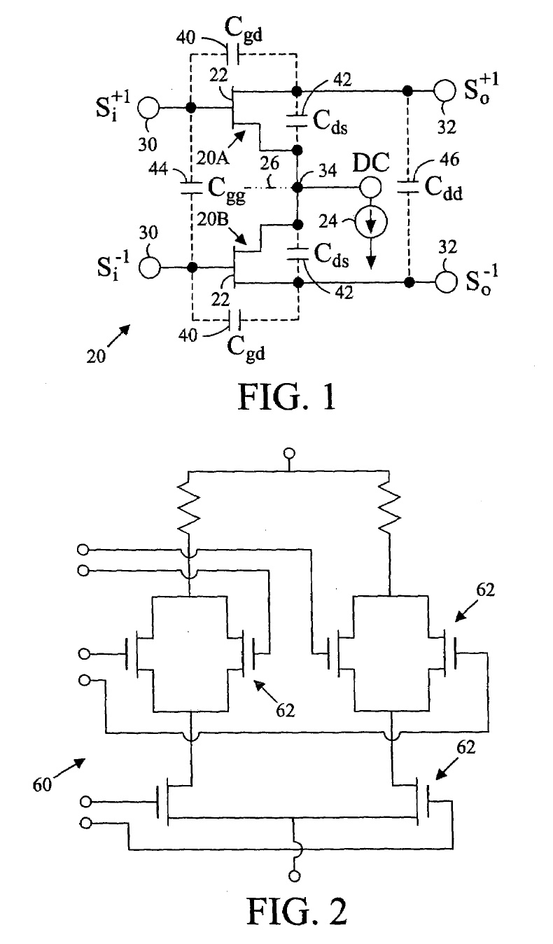

Referring in detail to the drawings where similar parts are identified by like reference numerals, and, more particularly to FIG. 1, a differential gain cell or amplifier 20 is a common elemental device of balanced or differential circuitry. For example, referring to FIG. 2, a Gilbert cell mixer 60, enabling frequency multiplication, comprises a plurality of differential gain cells 62.

A differential gain cell 20 comprises two nominally identical circuit halves 20A, 20B. When biased, with a DC potential, from, for example, a DC current source 24, and stimulated with a differential mode signal, comprising even and odd mode components of equal amplitude and opposite phase (Sᵢ⁺¹ and Sᵢ⁻¹) 30, 32, a virtual ground is established at the symmetrical axis 26 of the two circuit halves. At the virtual ground, the potential at the operating frequency does not change with time regardless of the amplitude of the stimulating signal. The quality of the virtual ground of a balanced device is independent of the physical ground path and, therefore, balanced or differential circuits can tolerate poor RF grounding better than circuits operated with single ended (ground referenced) signals. Differential devices can also typically operate with lower signal power and at higher data rates than single ended devices and have good immunity to noise, including noise at even-harmonic frequencies, from external sources such as adjacent conductors.

However, the response of integrated circuits, including differential amplifiers, to high frequency signals is typically frequency dependent. Integrated circuits are fabricated by depositing layers of conductive, semi-conductive and insulating materials on a semi-conductive substrate and inherent frequency dependent connections commonly exist between various elements of the circuit components and between the various elements of the circuit components and the substrate on which the circuit's components are fabricated. One such inherent frequency dependent connection comprises a capacitive connection of the gates and drains of MOS transistors and the bases and collectors of bipolar junction (BJT) transistors. For example, an intrinsic parasitic capacitance (C_{gd}) 42 interconnects the gate and the drain of a typical MOS transistor because the drain dopant diffuses under the oxide comprising the transistor's gate. As the frequency of the stimulating signal increases, the impedance of the interconnection of the gate and the drain of the transistor and, therefore, the input impedance of the differential gain cell changes. Moreover, due to the gain of the transistor, any change in voltage at the gate of the transistor is amplified at the drain of the transistor causing the parasitic capacitance (C_{gd}) to appear to be a much larger capacitor; a phenomenon known as the Miller effect.

The parasitic gate-to-drain capacitance is only one source of frequency dependent variability in the operation of a differential amplifier. As a result of the fabrication of closely spaced circuit components on a semi-conductive substrate, parasitic capacitance (C_{ds}) 42 connects the source terminals to the drain terminals of MOS transistors (collector and emitters of BJTs); parasitic capacitance C_{gg} 44 connects the gate terminals of the two transistors, the input terminals of the amplifier; and C_{dd} 46 connects the drain terminals of the transistors, the amplifier's outputs. These inherent capacitive parasitic interconnections in the integrated circuit contribute additional frequency dependent variability to the output signal of the amplifier. The inventors recognized that the respective input signals and the respective output signals of the differential amplifier comprise mirror image signal components of substantially equal amplitude and opposite phase. The inventors concluded that the effect of the parasitic capacitance connecting the terminals of the transistors of a differential amplifier could be substantially reduced or eliminated by connecting each conductor of an amplifier input signal component to the respective conductor of the output signal component of opposite phase.

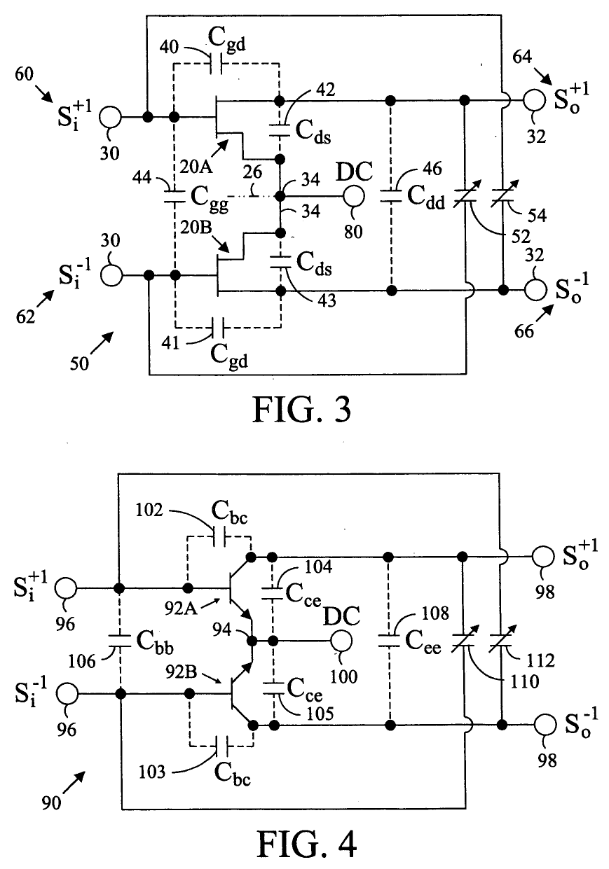

Referring to FIG. 3, a unilateralized amplifier 50 comprises a differential gain cell including matched transistors 20A and 20B. The source terminals 34 of the transistors are interconnected and connected to a source of DC bias 80, for examples, a ground potential or a DC current source. The gate terminals 30 of the respective transistors are arranged to conduct a differential input signal comprising the component signal, Sᵢ⁺¹, 60 and its complementary differential input signal component, Sᵢ⁻¹, 62. The components of the differential input signal are mirror image, modulated signals of substantially equal amplitude and opposite phase, that is, the phase angle of one component of the input signal is shifted 180° relative to the phase angle of the second component. Likewise, the components of the differential output signal, Sₒ⁺¹, 64 and Sₒ⁻¹, 66, conducted by the drain terminals 32 of the respective transistors, are respectively in phase with the input signal to the transistor and, therefore, opposite in phase to each other and, since the transistors are matched, have substantially equally amplitude.

Inherent in the structure of the transistors 20A, 20B is parasitic capacitance (C_{gd}) 40, 41 interconnecting the respective gate 30 and drain 32 of each transistor. The gates and drains of the two transistors comprise, respectively, the input terminals and the output terminals of the amplifier. Due the gain (A) of the transistor, a change in voltage (dV) at the gate of a transistor is amplified at the drain (A*dV) causing the opposing sides of the parasitic capacitance to experience differing voltage. As a result of a phenomenon known as the Miller effect, the parasitic capacitance (C_{gd}) has the effect of a larger capacitor causing the input impedance of the differential amplifier to vary substantially with frequency and producing substantial frequency dependent variability in the output signal of the amplifier.

In addition, inherent parasitic capacitance, (C_{ds}) 42, 43 connects the respective sources and drains of the two transistors, producing a frequency variable conductive path between the amplifier's outputs and the conductor through which the transistors are biased. Likewise, parasitic capacitance (C_{gg}) 44 connects the gate terminals, the amplifier's inputs; and parasitic capacitance, C_{dd}, 46 connects drain terminals of the transistors, the differential amplifier's outputs. These capacitive parasitic interconnections of the terminals of the transistors produce additional frequency dependent variability in the impedance of the differential amplifier and, therefore, additional frequency dependent variability in the amplifier's performance.

To reduce or eliminate the effect of the inherent parasitic capacitance in the transistors of the differential amplifier and provide a more stable amplifier with a more linear response, compensating capacitors 52 and 54 are connected from the gate of each transistor, for example the gate of transistor 20A, to the drain of the second transistor of the differential gain cell, for example the drain of transistor 20B, connecting each conductor of an input signal component to the respective conductor of the output signal component of opposite phase. Since the transistors of the differential gain cell are matched and the phase of the differential input signal component Sᵢ⁺¹ is displaced 180° from the phase of the differential output signal component Sₒ⁻¹, the change in voltage at the drain of a transistor due to the parasitic capacitance, is offset by the voltage at the respective compensating capacitor 52, 54 and the input impedance of the test structure remains more constant with frequency. The Miller effect produces substantial variability in the output of the amplifier and can be countered with compensating capacitors having capacitances substantially equal to the parasitic input to output (source to drain) capacitance (C_{gd}). The effects of input signal frequency on amplifier output can be further reduced by providing compensating capacitance substantially equaling the capacitance of the parasitic input to output (source to drain) capacitance (C_{gd}) and the capacitance, C_{ds}, C_{gg} or C_{dd}, of one more of the parasitic interconnections of the terminals of the transistors. The compensating capacitors preferably have values equal to the combined parasitic capacitances, C_{gd}, C_{ds}, C_{gg} and C_{dd} to offset the Miller effect and the effects of the parasitic capacitances connecting the terminals of the transistors of the differential amplifier.

Since the magnitude of the capacitance of the parasitic interconnections in the transistors may not be known with precision, the capacitance of the compensating capacitors may be adjustable. Adjustment may be accomplished mechanically or electronically, through a varactor or otherwise, or by trimming a fixed capacitor in the integrated circuit.

Integrated circuit-based amplifiers constructed with other types of transistors also experience input signal frequency dependent instability and non-linearity. Referring to FIG. 4, the unilateralized differential amplifier 90 comprises a pair of bipolar junction (BJT) transistors 92A, 92B having the emitters 94 connected together and interconnected to a source of DC bias 100. Bipolar junction transistors also inherently include capacitive interconnections between the terminals of the transistor. Parasitic capacitance (C_{bc}) 102, 103 interconnects the base of each transistor and its respective collector, the inputs and outputs of the differential amplifier. The base to collector capacitance has the effect of a larger capacitor because of the Miller effect. Additional parasitic capacitances (C_{ce}) 104, 105 interconnect each collector and the respective emitter, the output of the amplifier and the amplifier's bias terminal; interconnect the conductors of the amplifier's input signal components (C_{bb}) 106 and the conductors of the amplifier's output signals (Cₑₑ) 108. Compensating capacitors 110, 112 connect each input of the amplifier to the amplifier output that conducts the output signal component having the opposite phase of the respective input to reduce the effect of input signal frequency on the performance of the amplifier. The compensating capacitors have a capacitance substantially equal to the capacitances of one or more of the parasitic interconnections of the terminals of the differential gain cell

The linearity and stability of a differential amplifier is improved by interconnecting each input of the amplifier to the respective output conducting the output signal of opposite phase with compensating capacitors having a capacitance substantially equal to the parasitic capacitances of the transistors of the amplifier.

The detailed description, above, sets forth numerous specific details to provide a thorough understanding of the present invention. However, those skilled in the art will appreciate that the present invention may be practiced without these specific details. In other instances, well known methods, procedures, components, and circuitry have not been described in detail to avoid obscuring the present invention.

All the references cited herein are incorporated by reference.

The terms and expressions that have been employed in the foregoing specification are used as terms of description and not of limitation, and there is no intention, in the use of such terms and expressions, of excluding equivalents of the features shown and described or portions thereof, it being recognized that the scope of the invention is defined and limited only by the claims that follow.

I (we) claim:

1. A differential amplifier comprising:
(a) a bias terminal;
(b) a first output;
(c) a first input, imposition of a first input signal having a first phase angle at said first input producing a first output signal having said first phase angle at said first output;
(d) a second output;
(e) a second input, imposition of a second input signal having an amplitude substantially equal to an amplitude of said first input signal and a second phase angle at said second input producing a second output signal having said second phase angle at said second output, said second phase angle being substantially opposite said first phase angle;
(f) a first compensating capacitor connecting said first input to said second output and having a capacitance substantially equaling a capacitance of a parasitic interconnection of said first input and said first output, and a capacitance of a parasitic interconnection of at least one of said first output and said bias terminal, said first and said second inputs, and said first and said second outputs; and
(g) a second compensating capacitor connecting said second input to said first output and having a capacitance substantially equaling a capacitance of a parasitic interconnection of said second input and said second output, and a capacitance of a parasitic interconnection of at least one of said second output and said bias terminal, said first and said second inputs, and said first and said second outputs.

2. The differential amplifier of claim 1 wherein at least one of said first and said second compensating capacitors has a capacitance that is variable.

3. A method for reducing an effect of a frequency of an input on an output of a differential amplifier, said input comprising a first input signal and a second input signal having a phase opposite of said first input signal and said output comprising a first output signal in phase with said first input signal and a second output signal in phase with said second input signal, said method comprising the steps of:
(a) interconnecting a conductor of said first input signal and a conductor of said second output signal, said interconnection comprising a capacitance substantially equaling a capacitance of a parasitic interconnection of said conductor of said first input signal and a conductor of said first output signal and a capacitance of a parasitic interconnection of at least one of said conductor of said second output signal and a conductor of an amplifier bias signal, said conductor of said first input signal and a conductor of said second input signal, and said conductor of said first output signal and said conductor of said second output signal; and
(b) interconnecting said conductor of said second input signal and said conductor of said second output signal, said interconnection comprising a capacitance substantially equaling a capacitance of a parasitic interconnection of said conductor of said second input signal and a conductor of said second output signal and a capacitance of a parasitic interconnection of at least one said conductor of said first output signal and said conductor of said amplifier bias signal, said conductor of said first input signal and said conductor of said second input signal, and said conductor of said first output signal and said conductor of said second output signal.

4. The method of claim 3 wherein a capacitance of at least one of said interconnection of said first input signal and said first output signal and said interconnection said second input signal and said second output signal is variable.
